(19) United States
(12) Patent Application Publication
(10) Pub. No.: US 2016/0362933 A1
(43) Pub. Date: Dec. 15, 2016

(54) TWO SIDED WINDOW TREATMENT/WALL ART

(71) Applicant: Lucy Mueller, Chicago, IL (US)

(72) Inventor: Lucy Mueller, Chicago, IL (US)

(21) Appl. No.: 14/735,863

(22) Filed: Jun. 10, 2015

(51) Int. Cl. E06B 9/386; H01L 51/52; H01L 51/00; H01L 27/32

(52) U.S. Cl. CPC E06B 9/386; H01L 27/3237; H01L 51/5253; H01L 51/5284; H01L 51/0097

(57) ABSTRACT

The present invention is a system for providing two sided art work for covering windows on the exterior walls of a room. The system comprises a sheet of material having graphics affixed on the front and back surfaces of the material and means for suspending the sheet of material across the window so as to expose the graphics for view from both the outside of the window and within the room in which the window is mounted. Different graphic displays may be affixed to the front and back surfaces of the material. In addition, the material of display artwork rather than conventional curtains, blinds, or shades known in the art. In a preferred embodiment the material includes a plurality of grommets upon which the material may be suspended across the window.

### BACKGROUND

A wide variety of devices exist for hanging of artwork on a wall and for mounting window treatments in a window. Conventional window treatments comprise fabric, blinds or shades which are hung from either a curtain rod, hooks, or in the case of shades are mounted on a shaft from which the shades are suspended and which can be rewound. It is further known to have a graphic design on the window treatment. However, a need exists for suspending artwork across unusually shaped windows, and for having the artwork displayed on both sides of the window treatment, including different artwork on each side. A variety of patents are directed to the hanging of such window treatments including U.S. Pat. Nos. 6,832,642; 5,673,741; U.S. Patent Publication No. 2004/0261959; and U.S. Patent Publication No. 2006/0102294. However, none of these references teach suggest or imply two sided artwork displayed on unusually shaped windows.

### BRIEF SUMMARY OF THE INVENTION

Conventional window treatments and window coverings are widely known. Typically they consist of fabric which is hung from a curtain rod. Other window coverings consist of material that is affixed as a permanent or non-removable shade or blind. Similarly, artwork in the form of fabric and other materials is frequently hung from a curtain rod or mounted over the interior of a window. However, the prior art does not appear to provide two sided artwork (graphics on both sides), for covering windows on the exterior walls of a room. Nor does it account for removable window coverings that are art. Accordingly, the present invention provides a system for displaying removable two-sided artwork across a window in which the graphics on the exterior side of the artwork facing outwardly toward the window have a first graphic design and the graphics on the interior side of the artwork have a second graphic display. Means are further provided for suspending the sheet of material across the window to expose the graphics for viewing from both outside the window and within the room in which the window is mounted. The sheet of material can be suspended across the window using a plurality of grommets extending through the material near the top end thereof. The grommets are preferably mounted parallel to the sheet of material so that the window treatment can be mounted flat against the window frame. The mechanism for suspending the sheet of material may further include a plurality of hooks affixed to and extend outwardly from the wall above the window which are sized constructed and arranged for insertion through the grommets and retention of the sheet of material thereon. Alternatively, two sided Velcro tape may be attached to the top portion of a sheet of material and a second piece of two sided Velcro tape can be attached to the top of the window frame so that when the first and second sections of Velcro tape are compressed against each other, interlock and suspend the sheet of two sided artwork.

In an additional alternative a curtain rod may be mounted on the wall above the top portion of the window and the artwork may include means for affixing itself to the curtain rod such as clips or rings. Alternatively, the sheet of material may be folded over itself so as to form a tube across the top portion of the material and the material may then be glued or stitched leaving a tubular aperture across the top of the material through which the curtain rod can be extended for mounting of the artwork.

In one embodiment, of the invention a coating is disposed on the outer surface of the artwork to protect against the effects of the sun. The coating can be a sheet of acrylic, and also can include light stabilizers and UV absorbers. The sheet of material itself can also be selected from the group comprising mylar, polyester, polypropylene polyethylene, acrylic or polycarbonate.

In one embodiment, the window of the present invention has a frame and the mechanism for suspending the sheet of material across the window comprises two sided pressure sensitive adhesive tape which may be disposed between the outer surface of the sheet of material and the window frame, Alternatively a plurality of pins may be mounted to the window frame and extend to the sheet of material. In one embodiment the pins may include clips for engaging the edges of the sheet of material and supporting the sheet of material thereon. Alternatively the pins may simply pierce the sheet of material proximate its top surface or its peripheral edges to support the sheet of material.

The sheet of material itself may be a selected from the group comprising fabric, canvas, paper, plastic film, paper mache, metal, wood or video screens. Although the sheet of material may be rectangular, it also could be circular or oval. Unusually shaped, usually means the window is at least three times longer than its width. In a further embodiment, the sheet of material comprises an organic light emitting diode screen, or thin film display, capable of displaying graphics thereon.

### BRIEF DESCRIPTION OF THE SEVERAL VIEWS OF THE DRAWINGS

FIG. 1 of the drawings is a front elevation view of a sheet of material having grommets proximate the top end thereof and graphics displayed on both the front and back surfaces of the sheet of material.

FIG. 2 of the drawings is a front perspective view of a door having a rectangular window directly adjacent thereto with the sheet of material of FIG. 1 mounted over the adjacent window.

FIG. 3 of the drawings is a rear elevation view of the sheet of FIG. 1 showing different graphics mounted thereon relative to the front surface of the sheet of material.

FIG. 4 of the drawings is a front elevation view showing a unusually shaped window and window frame.

FIG. 5 of the drawings is a front perspective view showing hooks which may be mounted above the window of FIG. 4 for mounting the sheet of FIG. 1 through the grommets extending through the sheet.

FIG. 6 of the drawings is a rear elevation view of the sheet of material of FIG. 3 showing two sided Velcro tape mounted to the top portion of the sheet of material.

FIG. 7 is a front perspective view of an alternative embodiment of the sheet material of FIG. 1 of the drawings in which the top portion of the sheet material is suspended from a curtain rod, in which the top portion of the sheet of material is folded over itself so as to form a tube across the top portion thereof and a curtain rod affixed to the wall is extended through the tubular portion of the sheet of materials so as to mount the artwork on the window.

FIG. 8 of the drawings is an front perspective view of an alternative embodiment of the system of FIG. 1 in which a plurality of clips are attached to the window frame at the top portion thereof and also are clipped to the sheet of material across the top portion of the sheet of material.

FIG. 9 of the drawings is an exploded view of the artwork of FIG. 1 in which a first surface of the sheet of material includes a coating thereon for a protection of the artwork against the effects of the sun.

FIG. 10 is a side perspective view of an alternative embodiment of the sheet of material of FIG. 1 in which a clear sheet of photo resistant plastic is disposed across the outer surface of the material for protection of the artwork from the effects of the sun.

FIG. 11 is a front perspective view of an alternative embodiment of the system of FIG. 1 in which two sided pressure sensitive adhesive tape is disposed between the outers surface of the sheet of material and the window frame shown in FIG. 4.

FIG. 12 of the drawings is a side perspective view of an alternative embodiment of the system for providing two sided artwork of FIG. 1 in which said sheet of material is supported on said window by a plurality of pins affixed to the window frame of FIG. 4 and the sheet of material proximate its peripheral edges.

FIG. 13 of the drawings is a side perspective view of an alternative embodiment of the system for hanging two sided artwork of FIG. 1 wherein the sheet of material comprises an organic light emitting diode screen capable of displaying graphics thereon as a thin film.

Certain embodiments are shown in the drawings. However, it is understood that the present disclosure is not limited to the arrangements and instrumentality shown in the attached drawings, wherein:

### DETAILED DESCRIPTION OF THE PREFERRED EMBODIMENT

For the purposes of promoting and understanding the principles disclosed herein, references are now made to the preferred embodiments illustrated in the drawings and specific language is used to describe the same. It is nevertheless understood that no limitation of the scope of the invention is thereby intended. Such alterations and further modifications in the illustrated device and such further applications of the principles disclosed as illustrated herein are contemplated as would normally occur to one skilled in the art to which this disclosure relates.

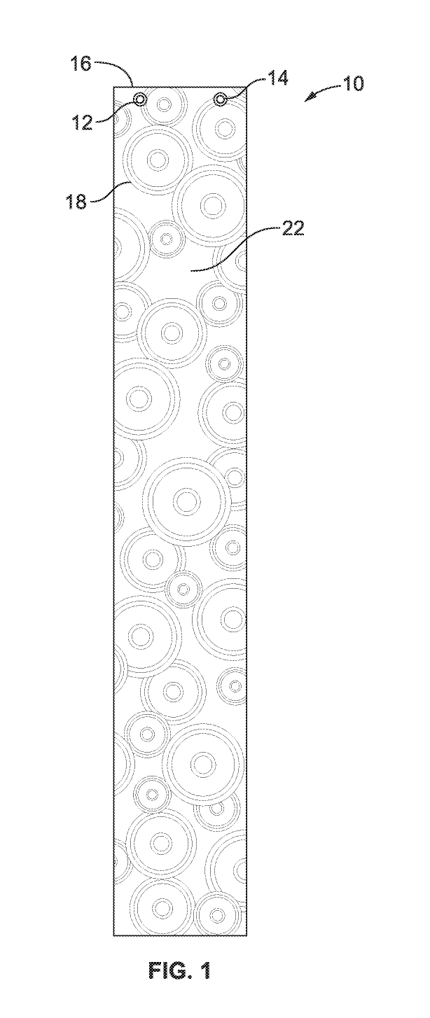

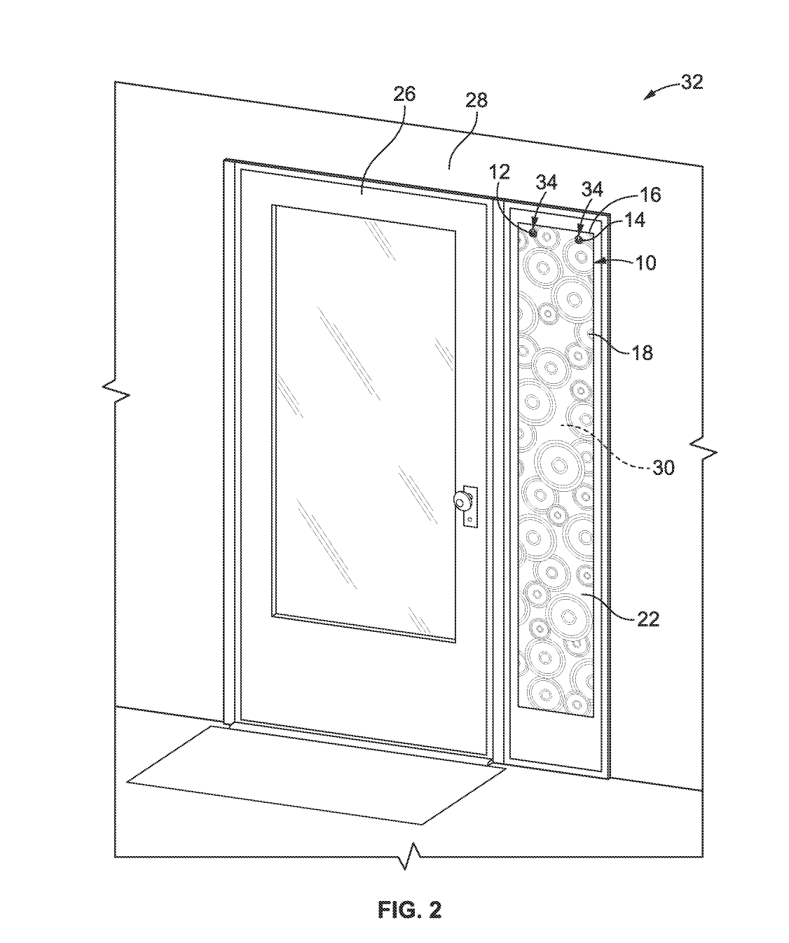

As best seen in FIG. 1 of the drawings, a sheet of material 10 has a pair of grommets 12 and 14 proximate the top end 16 of the sheet of material, and extending through the sheet of material and parallel thereto. Graphics 18 and 20 are disposed on the front surface 22 and the rear surface or back surface 24 of the sheet of material 10. As seen in FIG. 2, a door 26 is mounted in a wall 28 and has a window 30 directly adjacent to the door 26. Door 26, wall 28 and window 30 are all positioned within a room 32 in which the window 30 is mounted. Window 30 is substantially rectangular and is approximately 4 or more time longer in height than in width.

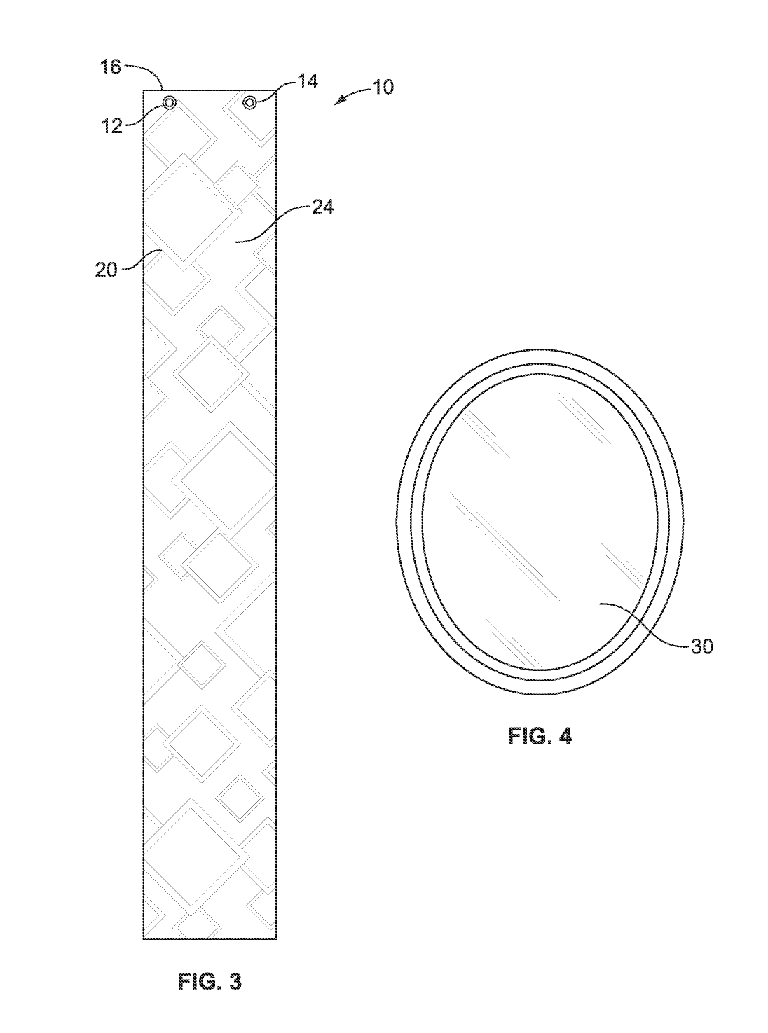

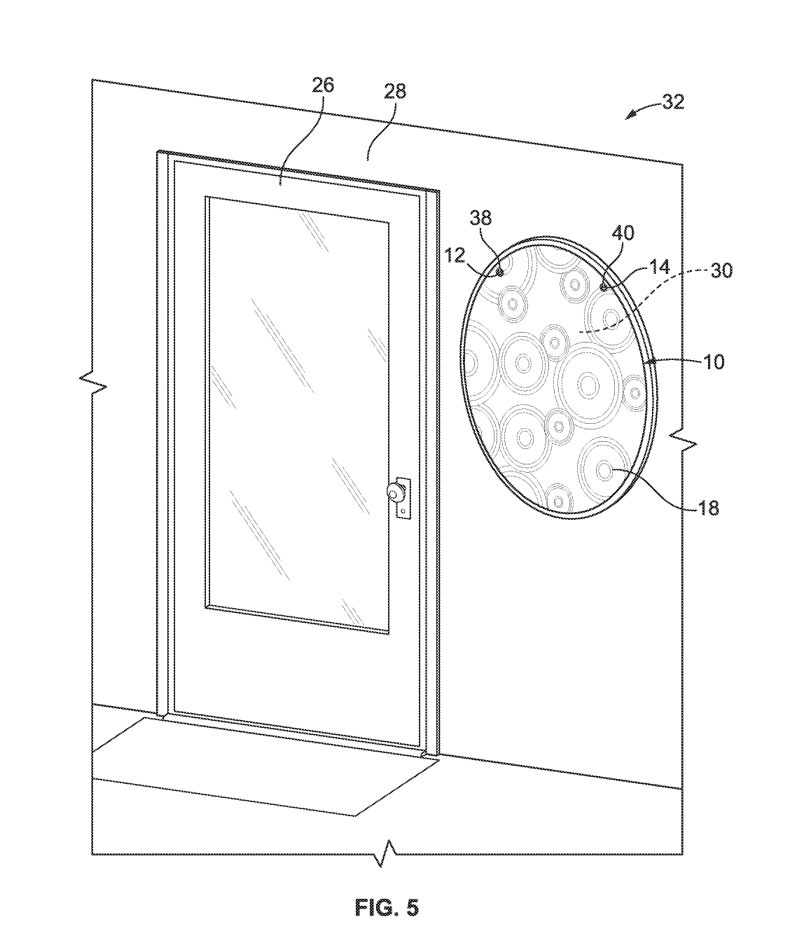

As further seen in FIGS. 1-5, a mechanism 34 is provided for suspending the sheet of material 10 across the window 30 so as to expose the graphics 18 and 20 for viewing from the outside 36 of the window and within the room 32 within which the window 30 is mounted. As further seen in FIG. 5, in one embodiment the mechanism 34 for suspending the sheet of material 10 comprises the plurality of hooks 38 and 40 affixed to and extending from the wall 28 above the window 30. The hooks 38 and 40 are sized constructed and arranged for insertion through the grommets 12 and 14 and for retention therein and for retention of the sheet of material 10 across the window.

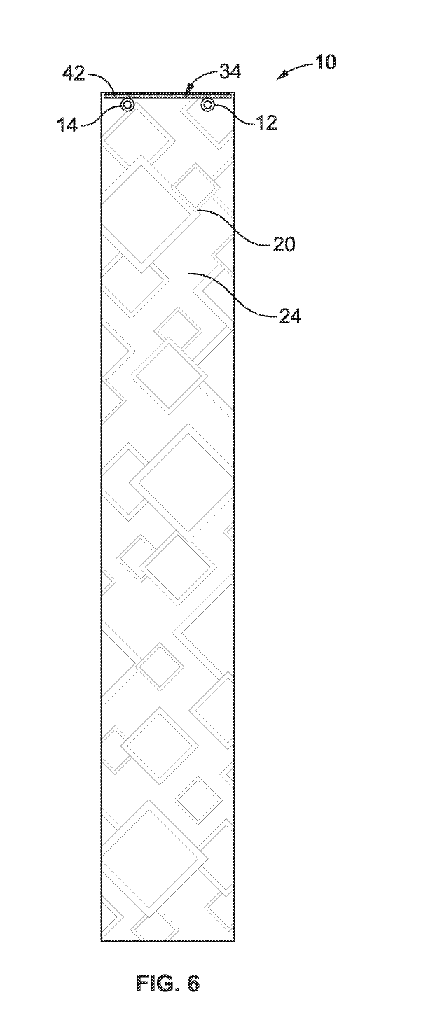

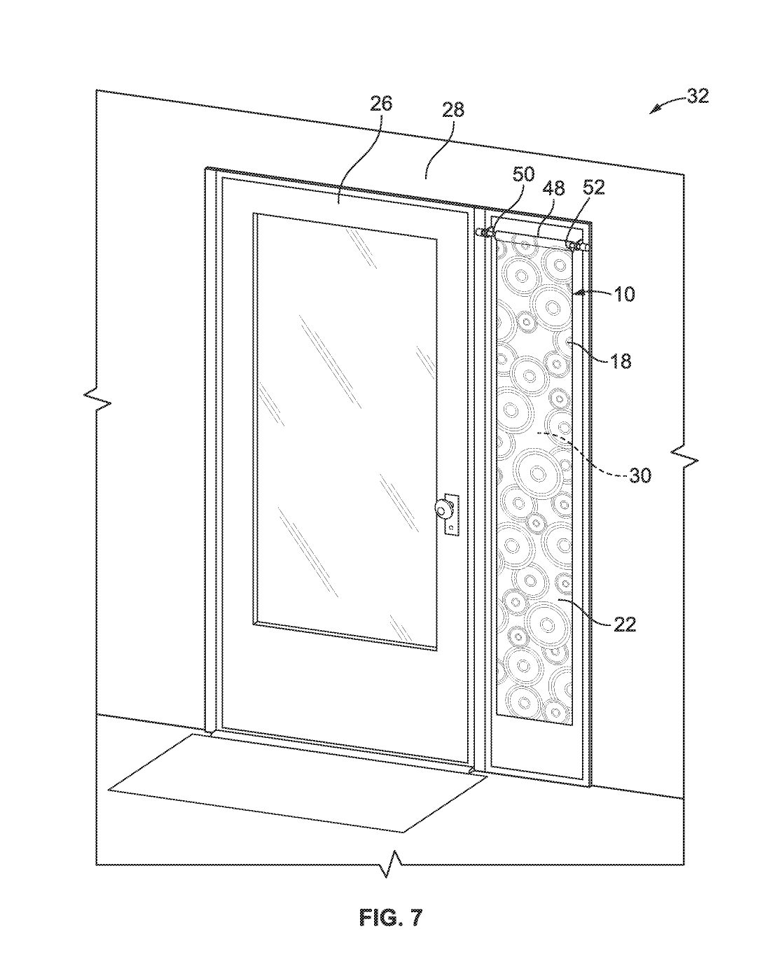

As seen in FIG. 6 of the drawings, the mechanism 34 for suspending the sheet of material 10 comprises a plurality of sections 42 and 44 of two sided velcro tape section 42 of the velcro tape is mounted to the window the top portion 46 of the window 30 and the second section 44 is mounted to the top portion 48. The first and second sections 42 and 44 may be compressed against each other thereby interlocking and suspending the sheet of material 10 across the window 30.

In an alternative embodiment of the invention, a curtain rod 50 is affixed to the wall 28 above the window 30. The top portion 48 of the sheet of material is folded over itself so as to form a tube 52 across the top portion 48 and the curtain rod extends through the tube 52 so as to mount the artwork 10 over the window 30.

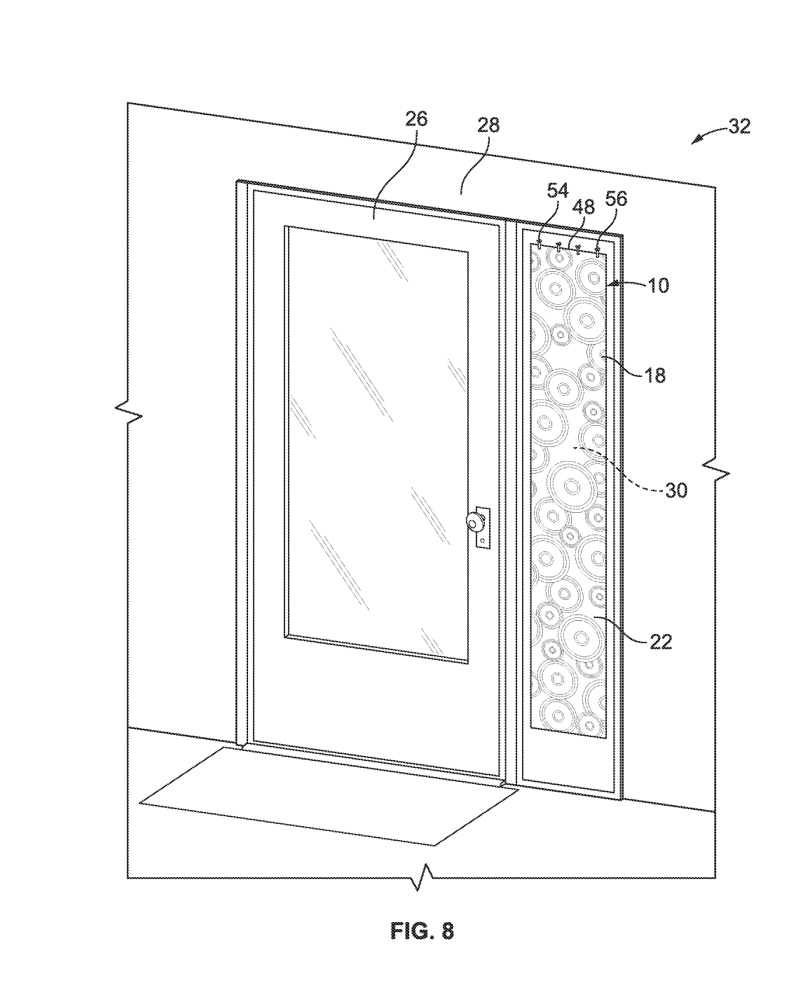

As seen in FIG. 8 of the drawings, a plurality of clips 54 and 56 are attached to the window frame at the top portion 46 of the window and are clipped to the sheet of material 10 proximate the top portion of the sheet of material 48 so as to suspend the sheet of material from the window.

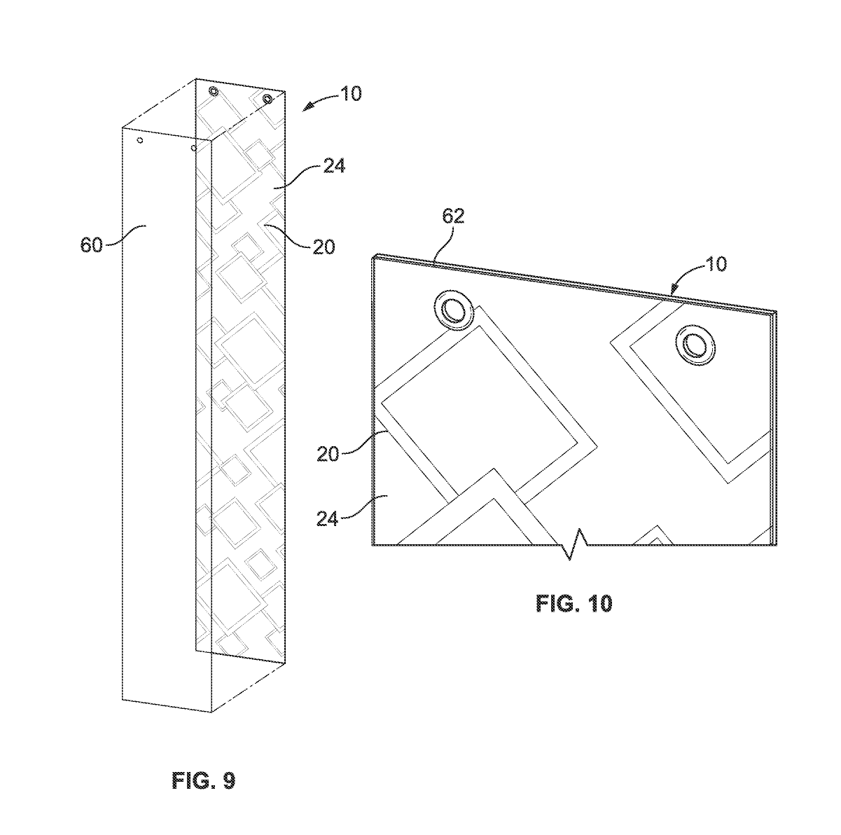

As seen in FIG. 9, the sheet of material 10 may include a coating 60 across the outer surface thereof for protection of the graphics 20 against the effects of the sun coming through the window 30.

In an alternative embedment shown in FIG. 10, a clear sheet of photo resistant plastic 62 is disposed across the rear surface 24 of the sheet of material 10 for protection of the graphics 20 against the effects of the sun.

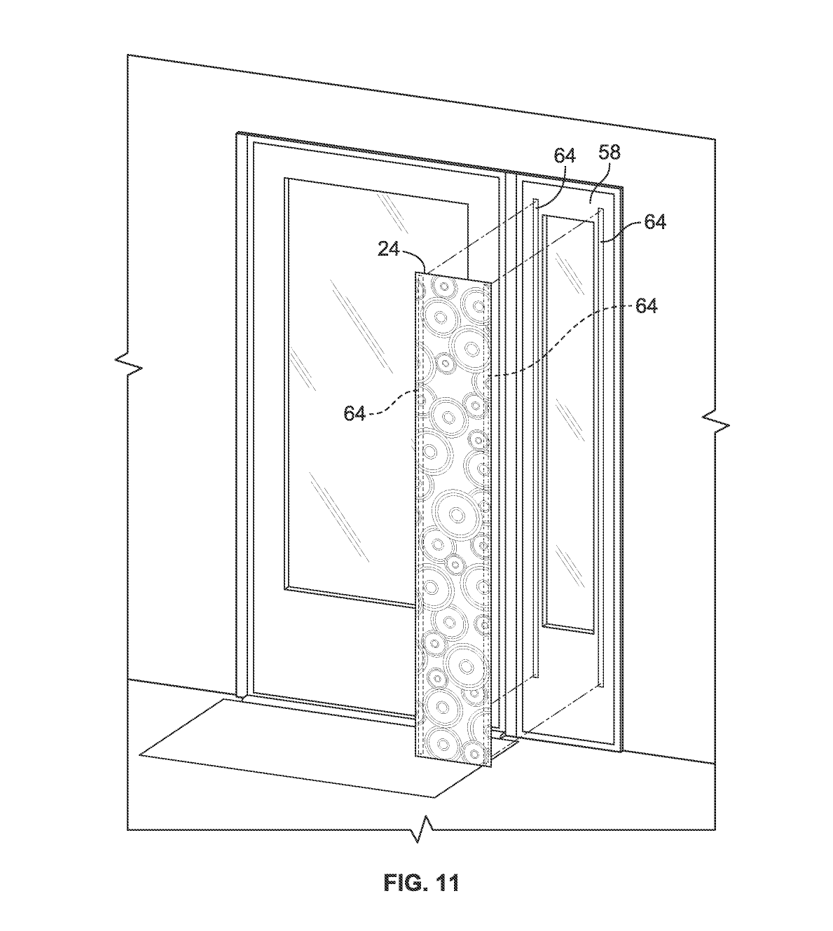

As shown in FIG. 11, in an alternative embodiment two sided pressure sensitive adhesive tape 64 is disposed between the rear surface 24 and the window frame 58 for mounting of the sheet of material 10.

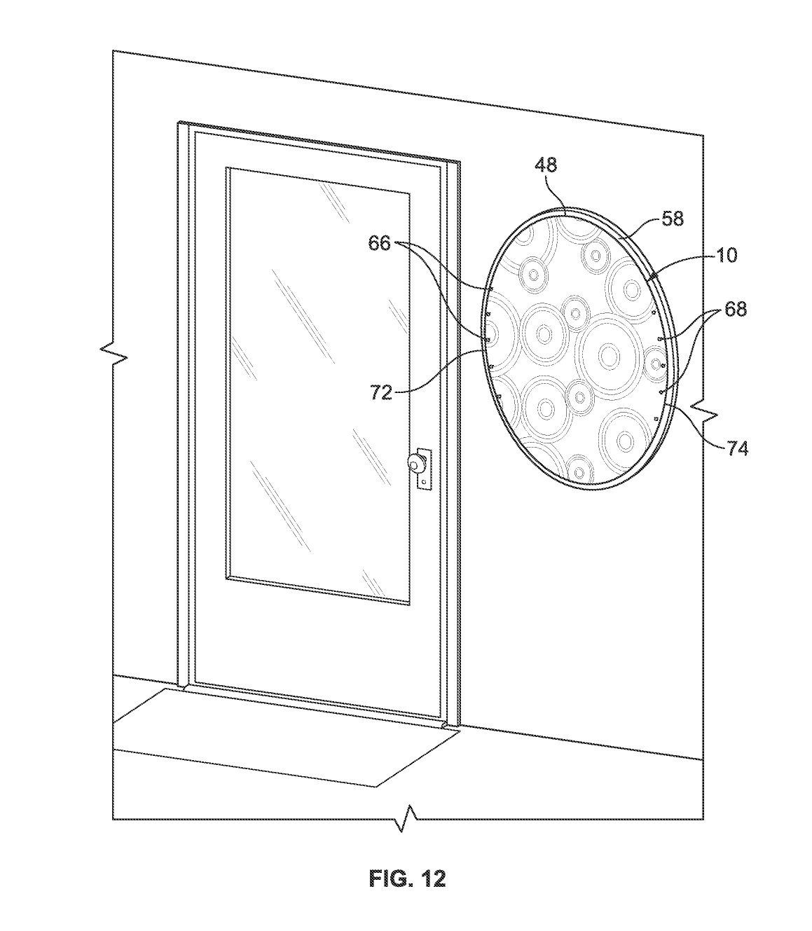

In an additional alternative embodiment shown in FIG. 12, the two sided art work 10 is supported on the window frame 58 by a plurality of pins 66 and 68 proximate its peripheral edges 70 by this it is meant that the pins can be affixed to the top portion 48 of the sheet of material or the sides 72 and 74 of the sheet of material 10. It should be noted that sheet of material 10 may be constructed of fabric, paper, plastic film, paper mache, metal or a video screen. When plastic is used the plastic may be mylar, acrylic or polycarbonate or even polyethylene, polyvinyl chloride or polypropylene. When UV stabilizers are required they may comprise benzophenones and other commonly known UV stabilizers. One such example is Nylostab light stabilizers.

As noted above the sheet of material is preferably rectangular although it may be circular, oval, or other desired geometric shapes. Window 30 is preferably at least three times longer than its width as is sheet of material 10.

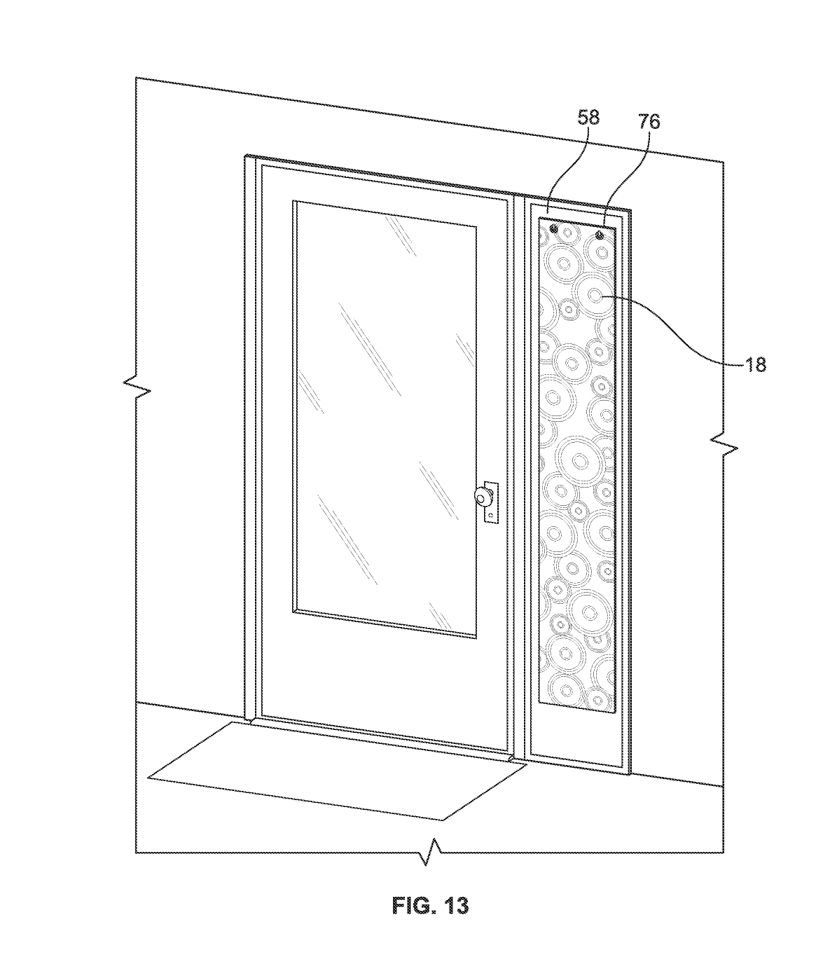

An additional alternative of the embodiment of the invention, sheet of material 10 may comprise an organic light emitting diode screen that may be sufficiently flexible to be rolled into a tube. One such example is manufactured by Sony as seen in FIG. 13. Light emitting diode screen 76 may be 80 micros thick or thicker as desired and the graphics 18 and or 20 may be full color other light emitting diode screens may also be utilized.

In a preferred embodiment sheet of material 10 is made of a stiff fabric such as canvas, and could be painted either before installation or by the user and can be sold blank or preapplied with graphics. Also solid colors can be utilized. In one embodiment a variety of sports teams logos, professional associations or colleges may be displayed on the graphics 18 and 20. Similarly photographs may be printed onto the canvas or plastic material. The graphics 18 and 20 of the sheet of material 10 may have patterns affixed there on which match their room decor. In one embodiment the sheet of material may be mounted within a frame 78 which in turn is hung from the window frame 58 for displaying the artwork from the front and back surfaces thereof.

While the particular preferred embodiments have been shown and described, it is obvious to those skilled in the art that changes and modifications may be made without departing from the teaching of the disclosure. The matter set forth in the foregoing description and accompanying drawings is offered by way of illustration only and not as limitation. The actual scope of the disclosure is intended to be defined in the following claims when viewed in their proper perspective based on the related art.

1. A system for providing two sided art work for covering windows on the exterior walls of a room said system comprising;
a sheet of material having graphics affixed thereon on the front and back surfaces of the material; and
means for suspending said sheet of material across said window so as to expose said graphics for viewing from both outside the window and within the room in which the window is mounted.

2. The system for providing two sided art work of claim 1 wherein said means for suspending said sheet of material across said window comprises a plurality of grommets extending through said material and parallel thereto proximate the top end thereof.

3. The system for providing two sided art work for windows of claim 2, said windows being mounted through a wall, wherein said means for suspending said sheet of material comprises a plurality of hooks affixed to said wall above said window, said hooks being sized constructed and arranged for insertion through said grommets and retention of said material thereon in a flat configuration.

4. The system for providing two sided art work of claim 1 wherein said means for suspending said sheet of material comprises a plurality of two sided Velcro tape, a first one of said sections of Velcro tape being mounted to said window and said second one of said sections of two sided Velcro tape being mounted to the top portion of said sheet of material proximate the top thereof, whereby said first and second sections of Velcro tape may be compressed against each other thereby interlocking and suspending said sheet of two sided art work.

5. The system for providing two sided art work of claim 1 wherein said means for suspending said rectangular sheet of material comprises a curtain rod mounted on said wall above said top portion of said window and means for affixing said two sided art work to said curtain rod.

6. The system for providing two sided art work of claim 1 wherein said sheet of material is folded over itself at the top portion thereof so as to form a tube across the top portion of said material, said tube being affixed to said top portion, and a curtain rod affixed to said wall which may be extended through said tubular portion so as to mount said art work on said window.

7. The system for providing two sided art work of claim 1 wherein said window has a frame and said means for mounting said sheet of material comprises a plurality of clips attached to said window frame at the top portion thereof and also clipped to said sheet of material across the top portion thereof.

8. The system for providing two sided art work of claim 1 wherein a first surface of said sheet of material includes a coating thereon for protection of said art work against the effects of the sun.

9. The system for providing two sided art work of claim 1 wherein the sheet of material comprises a clear sheet of photo resistant plastic material across the outer surface thereof for protection of said art work from the effects of the sun.

10. The system for providing two sided art work of claim 9 wherein said sheet of plastic material comprises acrylic.

11. The system for providing two sided art work of claim 9 wherein said sheet of material comprises light stabilizers and UV absorbers.

12. The system for providing two sided art work of claim 9 wherein said sheet of material be selected from the group comprising Mylar, acrylic or polycarbonate.

13. The system for providing two sided art work of claim 9 wherein said UV stabilizers comprise benzophenones.

14. The UV stabilizers of claim 12 comprise Nylostab™ light stabilizers.

15. The system for providing two sided art work for windows of claim 1 wherein said window has a frame and said means for suspending said sheet of material across said window comprises two sided pressure sensitive adhesive tape which may be disposed between said outer surface of said sheet of material and said window frame, including all or a portion of said window frame sufficient to support said sheet of material thereon.

16. The system for providing two sided art work for windows of claim 7 wherein said means for supporting said sheet of material comprises a plurality of pins mounted to said window frame and extending to said sheet of material, said pins including clips for engaging the edges of said sheet of material and supporting said sheet of material thereon.

17. The system for providing two sided art work for windows of claim 7 wherein said means for supporting said sheet of material comprises a plurality of pins affixed to said window frame and said sheet of material proximate its peripheral edges.

18. The system for providing two sided art work of claim 1 wherein said sheet of material is selected from the group comprising fabric, paper, plastic film, paper mache, metal, and video screens.

19. The system of claim 1 wherein said sheet of material is rectangular.

20. The system of claim 19 wherein said window is at least three times longer than its width as is said sheet of material.

21. The system of claim 21 wherein said sheet of material comprises an organic light emitting divide screen capable of displaying graphics thereon.

22. A multifunction wall hanging and window treatment comprising a system for providing two sided art work for covering windows on the exterior walls of a room said system comprising; a sheet of material having graphics affixed thereon on the front and back surfaces of the material; and means for suspending said sheet of material across said window so as to expose said graphics for viewing from both outside the window and within the room in which the window is mounted, said means for suspending said sheet of material across said window comprising a plurality of grommets extending through said material and parallel thereto proximate the top end thereof.

23. A multifunction wall hanging treatment comprising a system for providing two sided art work for the walls of a room said system comprising; a sheet of material having graphics affixed thereon on the front and back surfaces of the material; and
means for suspending said sheet of material on said wall to be reversed, said means for suspending said sheet of material on said wall comprising a plurality of grommets extending through said material and parallel thereto proximate the top end thereof, and a plurality of hooks for hanging said material on said grommets.
